(19) United States
(12) Patent Application Publication
(10) Pub. No.: US 2003/0134234 A1
(43) Pub. Date: Jul. 17, 2003

(54) Photoresist stripping solution and a method of stripping photoresists using the same

(76) Inventors: Kazumasa Wakiya, Kanagawa-ken (JP); Masakazu Kobayashi, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 10/303,783

(22) Filed: Nov. 26, 2002

Related U.S. Application Data
(63) Continuation of application No. 09/749,400, filed on Dec. 28, 2000, now abandoned.

(30) Foreign Application Priority Data
Dec. 28, 1999 (JP) 375267/1999

(51) Int. Cl. G03F 7/32; G03F 7/42; G03F 7/30

(52) U.S. Cl. 430/329; 430/331

(57) ABSTRACT

Disclosed herein is a photoresist stripping solution comprising (a) a nitrogen-containing organic hydroxyl compound, (b) a water soluble organic solvent, (c) water, and (d) a specific benzotriazole compound, and a method of stripping photoresists using the same. According to the invention, there are provided a photoresist stripping solution, which is particularly suitable for SiO₂ substrates utilized in liquid-crystal panel devices, and is excellent not only in preventing substrates from corrosion having metallic conductor patterns, particularly copper (Cu) conductor patterns, formed thereon, or substrates having metallic conductor patterns and overlying inorganic material layers formed thereon, but also in stripping photoresist layers as well as modified photoresist films, and a method for removing a photoresist using said stripping solution.

### BACKGROUND OF THE INVENTION

1. Field of the Invention

This invention relates to a photoresist stripping solution and a method of stripping photoresists using the same. More particularly, the invention relates to a photoresist stripping solution excellent not only in stripping photoresists but also in protecting substrates from corrosion, having metallic conductor patterns, especially copper (Cu) conductor patterns, formed thereon, or having metallic conductor patterns and overlying inorganic material layers formed thereon. The invention also relates to a method of stripping photoresists using said stripping solution. The invention is suitable for use in the fabrication of semiconductor devices, such as ICs and LSIs, as well as liquid-crystal panel devices.

2. Description of Relevant Art Semiconductor devices, such as ICs and LSIs, and liquid-crystal panel devices are fabricated by a process comprising: forming a conductive metallic film, such as a tin oxide film, and an overlying insulation film, such as an SiO₂ film, on a substrate by CVD or other methods; applying a uniform photoresist coat on the insulation film; selectively exposing and developing the photoresist coat to form a photoresist pattern; performing selective etch of the substrate as it carries the conductive metallic film and the insulation film to form a fine-line circuit, with the photoresist pattern used as a mask; and stripping away the unwanted photoresist layers using a stripping solution.

In the current fabrication process of semiconductor devices and liquid-crystal devices, dry etching, ashing, ion implantation and other post-treatments are applied to photoresist layers, and that it becomes necessary to strip away thusly treated photoresist layers. Due to those post-treatments, the photoresist layers become-modified films or deteriorated films. With the recent increase in the strictness of the conditions for these post-treatments, the nature of the deteriorated photoresist films tends to become inorganic rather than organic in nature. Particularly, in the case where the substrate is subjected to ashing, modified photoresist films and other residues such as metal depositions, which are built up by etching metallic films, adhere to or remain as referred to “veil” or “side walls” on the bottom or inner side wall of patterned grooves. Therefore, such modified photoresist films as well as those ashing residues and depositions should be stripped away.

With the recent tendency in the art to increase the degree of integration of semiconductor devices while reducing the chip size, efforts are being made to increase the feature size of wiring circuits and the number of their levels. However, this has met with two difficulties peculiar to semiconductor devices, one being the resistance of the metallic films used, which is commonly called “wiring resistance”, and the other being the wiring delay due to the wiring capacity. To lower the wiring resistance, it has been proposed and is now being commercialized to replace the conventionally used wiring material aluminum (Al) by a metal of lower resistance such as copper (Cu).

In addition, in the current photolithography technique, the technique for stripping a photoresist film is demanded to satisfy severer conditions corresponding to miniaturization of the pattern, progress in multilayerization of the substrate and change in materials formed on the surface of the substrate.

Particularly, in the fabrication of a liquid-crystal display device, as a substrate is used having formed on a metallic conductor pattern and an overlying inorganic material layer, such as an annealed polysilicon film and an amorphous silicon film, development of such a stripping solution is demanded that can strip away the photoresist film without causing corrosion to both the metallic conductor pattern and the inorganic material layer.

Under these circumstances, a stripping solution that contains an organic amine as an essential ingredient is commonly used, because of its effectiveness in stripping photoresists and in protecting substrates from corrosion. Examples of the stripping solution include a resist stripping liquid composition containing an organic amine, a specific surfactant, a non-protonic polar solvent and water (JP-A-7-64297), a positive-working photoresist stripping solution containing a nitrogen-containing organic hydroxyl compound and a specific aromatic hydroxyl compound, and further, a triazole compound and a water soluble organic solvent optionally added thereinto (JP-A-7-120937), a positive-working photoresist stripping solution containing N,N-diethylhydroxylamine (JP-A-7-271057), and a resist stripping liquid composition containing an amine having pKa of 7.5-13, a hydroxylamine, a water soluble organic solvent, an anticorrosive agent and water in specific proportions (Japanese Patent No. 2,911,792). U.S. Pat. No. 5,648,324 discloses a photoresist stripping liquid composition containing an organic polar solvent, an alkanolamine and 2,2′-{[(methyl-1H-benzotriazole-1-yl)methyl]imino}bisethanol in specific proportions. Furthermore, U.S. Pat. No. 5,597,678 discloses a stripping liquid composition containing a specific water soluble organic solvent, an anticorrosive agent, an alkanolamine, water and a water soluble surfactant.

However, it is difficult to attain both corrosion prevention of a substrate having a metallic conductor pattern, particularly Cu conductor pattern, formed thereon or a substrate having a metallic conductor pattern and an overlying inorganic material layer, and strippability of a photoresist film and a modified film, with good balance, by the foregoing conventional stripping liquid compositions.

### SUMMARY OF THE INVENTION

An object of the invention is to provide a photoresist stripping solution, which is particularly suitable for SiO₂ substrates utilized in liquid-crystal panel devices, and is excellent not only in preventing substrates from corrosion having metallic conductor patterns, particularly copper (Cu) conductor patterns, formed thereon, or substrates having metallic conductor patterns and overlying inorganic material layers formed thereon, but also in stripping photoresist layers as well as modified photoresist films.

Another object of the invention is to provide a method of stripping photoresists using the above-described stripping solution.

Thus, according to its first aspect of the invention provides a photoresist stripping solution comprising (a) a nitrogen-containing organic hydroxyl compound, (b) a water soluble organic solvent, (c) water, and (d) a benzotriazole compound represented by the following general formula (I):

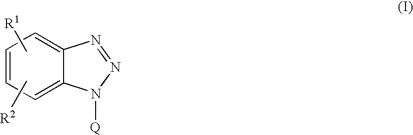

wherein Q is a hydrogen atom, a hydroxyl group or a substituted or unsubstituted hydrocarbon group having 1-10 carbon atoms (provided that said hydrocarbon group may have an amide bond or an ester bond in the structure), an aryl group or the following formula:

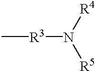

(wherein R³ represents an alkyl group having 1-6 carbon atoms; and R⁴ and R⁵ are each independently a hydrogen atom, a hydroxyl group or a hydroxyalkyl group or an alkoxyalkyl group having 1-6 carbon atoms); and R¹ and R² are each independently a hydrogen atom, a substituted or unsubstituted hydrocarbon group having 1-10 carbon atoms, a carboxyl group, an amino group, a hydroxyl group, a cyano group, a formyl group, a sulfonylalkyl group or a sulfo group.

According to its second aspect, the invention provides a method of stripping photoresists comprising: etching a substrate, which have a metallic conductor pattern formed thereon, or have a metallic conductor pattern and an overlying inorganic material layer formed thereon, using a photoresist pattern formed on the substrate as a mask; and stripping the photoresist pattern using the forgoing photoresist stripping solution.

According to its second aspect, the invention also provides a method of stripping photoresists comprising: etching a substrate, which have a metallic conductor pattern formed thereon, or have a metallic conductor pattern and an overlying inorganic material layer formed thereon, using a photoresist pattern formed on the substrate as a mask; ashing the substrate; and stripping residues occurred after ashing using the foregoing photoresist stripping solution.

### DETAILED DESCRIPTION OF THE INVENTION

The invention will be described in detail below.

According to the first aspect of the invention, component (a) in the stripping solution is a nitrogen-containing organic hydroxyl compound. As component (a), any organic hydroxyl compound containing a nitrogen atom in the molecule thereof can be arbitrarily used. Among them, an amine having acid dissociation exponents (pKa) in an aqueous solution at 25° C. of 7.5-13 is preferable, from the view point of corrosion prevention to a substrate having a metallic conductor pattern, such as made of Cu, Al and an Al alloy, or a substrate having a metallic conductor pattern and an overlying inorganic material layer, such as a polysilicon film and an amorphous silicon film, formed thereon. As the amine, alkanolamines are preferably used.

Exemplary alkanolamines include monoethanolamine, diethanolamine, triethanolamine, 2-(2-aminoethoxy)ethanol, N,N-dimethylethanolamine, N,N-diethylethanolamine, N,N-dibutylethanolamine, N-methylethanolamine, N-ethylethanolamine, N-butylethanolamine, N-methyldiethanolamine, monoisopropanolamine, diisopropanolamine and triisopropanolamine. Among these amines, monoethanolamine, diethanolamine and 2-(2-aminoethoxy)ethanol are preferred. Component (a) may be used either alone or in combination with themselves.

Component (b) is a water-soluble organic solvent. It is not specifically restricted so long as it is miscible with water and that allows other components (a) and (d) employed in the invention be dissolved in the solution.

Examples of such water-soluble organic solvents include sulfoxides, such as dimethyl sulfoxide; sulfones, such as dimethyl sulfone, diethyl sulfone, bis(2-hydroxyethyl) sulfone and tetramethylene sulfone; amides, such as N,N-dimethylformamide, N-methylformamide, N,N-dimethylacetamide, N-methylacetamide and N,N-diethylacetamide; lactams, such as N-methyl-2-pyrrolidone, N-ethyl-2-pyrrolidone, N-propyl-2-pyrrolidone, N-hydroxymethyl-2-pyrrolidone and N-hydroxyethyl-2-pyrrolidone; imidazolidinones, such as 1,3-dimethyl-2-imidazolidinone, 1,3-diethyl-2-imidazolidinone and 1,3-diisopropyl.-2-imidazolidinone; polyhydric alcohols and derivatives thereof, such as ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monoalkyl ether (wherein alkyl is a lower alkyl of 1-6 carbon atoms), such as diethylene glycolmonomethyl ether, diethylene glycol monoethyl ether, diethylene glycol monopropyl ether and diethylene glycol monobutyl ether. Among these, preferable ones are dimethyl sulfoxide, N-methyl-2-pyrrolidone and diethylene glycol monobutyl ether because of its strippability of photoresists and anti-corrosive ability against substrates. Among all, dimethyl sulfoxide, N-metyl-2-pyrrolidone are particularly preferable. Component (b) may be used either alone or in combination with themselves.

Component (d) is a benzotriazole compound represented by the following general formula (I):

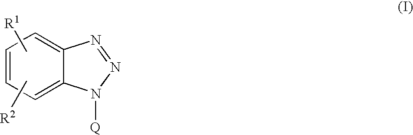

wherein Q is a hydrogen atom, a hydroxyl group or a substituted or unsubstituted hydrocarbon group having 1-10 carbon atoms (provided that said hydrocarbon group may have an amide bond or an ester bond in the structure), an aryl group or the following formula:

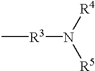

(wherein R³ represents an alkyl group having 1-6 carbon atoms; and R⁴ and R⁵ are each independently a hydrogen atom, a hydroxyl group or a hydroxyalkyl group or an alkoxyalkyl group having 1-6 carbon atoms); and R¹ and R² are each independently a hydrogen atom, a substituted or unsubstituted hydrocarbon group having 1-10 carbon atoms, a carboxyl group, an amino group, a hydroxyl group, a cyano group, a formyl group, a sulfonylalkyl group or a sulfo group.

The term “hydrocarbon group” means an organic group consisting of carbon and hydrogen atoms. In the definition of the groups Q, R¹ and R² as specified in the present invention, each of the hydrocarbon groups may be an aromatic hydrocarbon group or an aliphatic hydrocarbon group, may be saturated or unsaturated, and may be a linear group or a branched group. Examples of a substituted hydrocarbon group include hydroxyalkyl groups and alkoxyalkyl groups.

for the pure copper-wired substrates, it is particularly preferable that Q in the above general formula (I) is a group represented by the following formula:

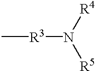

wherein R³, R⁴ and R⁹ are each as defined above. In the above formula, it is particularly preferable that R⁴ and R⁵ are each independently a hydroxyalkyl group or an alkoxyalkyl group having 1-6 carbon atoms. When at least one of R⁴ and R⁵ is an alkyl group having 1-6 carbon atoms, the benzotriazole compound has a poor solubility in water. However, it is preferred to use such a compound in the case where the stripping solution contains other component allowing the dissolution of this compound.

In the general formula (I), Q preferably forms a water-soluble group and to give specific examples, a hydrogen atom, an alkyl group having 1-3 carbon atoms (i.e., methyl, ethyl, propyl or isopropyl), a hydroxyalkyl group having 1-3 carbon atoms and a hydroxyl group are particularly preferred from the viewpoint of effective protection of inorganic material films from corrosion.

Specific examples of the benzotriazole compounds as component (d) includebenzotriazole, 5,6-dimethylbenzotriazole, 1-hydroxybenzotriazole, 1-methylbenzotriazole, 1-aminobenzotriazole, 1-phenylbenzotriazole, 1-hydroxymethylbenzotriazole, 1-benzotriazole-methyl carboxylate, 5-benzotriazole-carboxylic acid, 1-methoxybenzotriazole, 1-(2,2-dihydroxyethyl)benzotriazole, 1-(2,3-dihydroxypropyl)benzotriazole, and products of “IRGAMET” series marketed from Ciba Speciality Chemicals Inc., such as 2,2′-{[(4-methyl-1H-benzotriazol-1-yl)methyl]imino}bisethanol, 2,2′-{[(5-methyl-1H-benzotriazol-1-yl)methyl]imino}bisethanol, 2,2′-{[(4-methyl-1H-benzotriazol-1-yl)methyl]imino}bisethane and 2,2′-{[(4-methyl-1H-benzotriazol-1-yl)methyl]imino}bispropane. Among these, it is particularly preferable to use 1-(2,3-dihydroxypropyl)benzotriazole, 2,2′-{[(4-methyl-1H-benzotriazol-1-yl)methyl]imino}bisethanol, 2,2′-{[(5-methyl-1H-benzotriazol-1-yl)methyl]imino}bisethanol, etc.

In the photoresist stripping solution of the invention comprising components (a), (b), (d), and water as component (c), the amounts of the respective components are as follows.

The upper limit of the amount of component (a) is preferably 65 wt %, more preferably 60 wt %. The lower limit thereof is preferably 10 wt %, more preferably 30 wt %. It is preferred to use by determining an appropriate amount of component (a) within the range of said amount depending on its acid dissociation exponent (pKa) inherent thereto. When the amount of component (a) is too large, corrosion is liable to occur to a substrate having a Cu conductor pattern formed thereon.

The upper limit of the amount of component (b) is preferably 60 wt % by weight, more preferably 40 wt %. The lower limit thereof is preferably 10 wt %, more preferably 20 wt %.

The upper limit of the amount of component (c) is preferably 50 wt % by weight, more preferably 40 wt %. The lower limit thereof is preferably 5 wt %, more preferably 10 wt %.

The upper limit of the amount of component (d) is preferably 10 wt %, more preferably 5 wt %. The lower limit thereof is preferably 0.1 wt %, more preferably 0.5 wt %. Component (d) particularly functions as an anticorrosive agent. When the amount of component (d) is less than the above-described range, the effect of protection of Cu from corrosion cannot be sufficiently obtained, and when it exceeds the above-described range, strippability of a photoresist film becomes poor.

In the invention, components (a) to (d) are incorporated in amounts of within the above-indicated range, whereby further superior effect is exhibited in strippability of a photoresist film and an ashing residue (a modified photoresist film, a metallic deposition) and in corrosion prevention of a metallic conductor pattern and an inorganic material layer, such as a polysilicon film.

Particularly, when the amounts of component (a) and component (d) are incorporated in amounts of within the above range, the corrosion prevention against a metallic conductor pattern, particularly a Cu conductor pattern, and further, an inorganic material layer can be more effectively achieved.

In the photoresist stripping solution of the invention, even though an anticorrosive agent commonly used for an ordinary amine series photoresist stripping solution, other than component (d), is substantially not contained, excellent corrosion prevention is achieved against a metallic conductor pattern, such as a Cu conductor pattern, and an inorganic material layer, such as amorphous silicon film and polysilicon film. Typical examples of such an anticorrosive agent include an aromatic hydroxyl compound, such as pyrocatechol, pyrogallol and hydroxybenzoic acid. It is not preferred to incorporate the aromatic hydroxyl compound in the stripping solution of the invention, as strippability of photoresists become lowered especially in the case where is used a substrate having a Cu conductor pattern as a metallic conductor pattern thereon.

In addition to components (a)-(d), at least one member selected from N-alkyl-2-pyrrolidone represented by the general

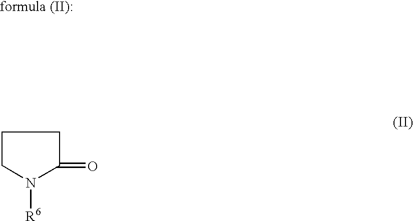

(where R⁶ is an alkyl group of 6-20 carbon atoms) and an acetylene alcohol/alkylene oxide adduct may optionally be added for enhancing the permeation of the solution and for further strippability of photoresist films and ashing residues such as modified photoresist films.

N-alkyl-2-pyrrolidone and an acetylene alcohol/alkylene oxide adduct are known per so as surfactants.

Specific examples of N-alkyl-2-pyrrolidone represented by the general formula (II) include N-hexyl-2-pyrrolidone, N-heptyl-2-pyrrolidone, N-octyl-2-pyrrolidone, N-nonyl-2-pyrrolidone, N-decyl-2-pyrrolidone, N-undecyl-2-pyrrolidone, N-dodecyl-2-pyrrolidone, N-tridecyl-2-pyrrolidone, N-tetradecyl-2-pyrrolidone, N-pentadecyl-2-pyrrolidone, N-hexadecyl-2-pyrrolidone, N-heptadecyl-2-pyrrolidone, N-octadecyl-2-pyrrolidone. Among these, N-octyl-2-pyrrolidone and N-dodecyl-2-pyrrolidone are preferred, and they are readily available as commercial products from ISP Japan Co., Ltd. under trade names “SURFADONE LP100” and “SURFADONE LP300”, respectively.

In the acetylene alcohol/alkylene oxide adduct, acetylene alcohol forms said adduct should preferably be one which is represented by the following general formula (III):

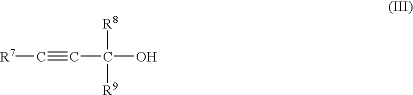

where R⁷ is a hydrogen atom or

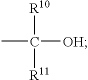

R⁸, R⁹, R¹⁰ and R¹¹ are each independently a hydrogen atom or an alkyl group having 1-6 carbon atoms.

The alkyl group having 1-6 carbon atoms includes, for example, methyl group, ethyl group, propyl group, isopropyl group, butyl group, isobutyl group, sec-butyl group, tert-butyl group, pentyl group, isopentyl group, neopentyl group, tert-pentyl group, hexyl group, isohexyl group, 3-methylpentyl group, 2,2-dimethylbutyl group, and 2,3-dimethylbutyl group.

The acetylene alcohol is commercially available under trade names of “Surfynol” and “Olfin” series (both are products of Air Product and Chemicals Inc.). Of these commercial products, “Surfynol 104”, “Surfynol 82”, or mixtures thereof are most preferred for its physical properties. Other products such as “Olfin B”, “Olfin P”, and “Olfin Y” may also be preferred.

The alkylene oxide to be added to the acetylene alcohol is preferably ethylene oxide, propylene oxide, or a mixture thereof.

Preferred compounds as acetylene alcohol/alkylene oxide adducts are those which are represented by the following general

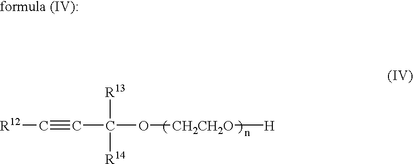

where R¹² is a hydrogen atom or

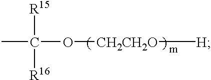

R¹³, R¹⁴, R¹⁵, and R¹⁶ are each independently a hydrogen atom or an alkyl group having 1-6 carbon atoms; (n+m) is an integer of 1 to 30, which is the number of ethylene oxide molecules added. This number subtly affects the water solubility and surface tension.

The acetylene alcohol/alkylene oxide adduct is commercially available under trade names of “Surfynol” series (products of Air Product and Chemicals Inc.) and “Acetylenol” series (products of Kawaken Fine Chemicals Co., Ltd.). Preferable among these products are “Surfynol 440” (n+m=3.5), “Surfynol 465 ” (n+m=10), “Surfynol 485” (n+m=30), “Acetylenol EL” (n+m=4), and “Acetylenol EH” (n+m=10), or mixtures thereof, in view of their water solubility and surface tension. A mixture of “Acetylenol EL” and “Acetylenol EH” in a ratio of from 2:8 to 4:6 (by weight) is particularly desirable.

In the photoresist stripping solution, the amount of these compounds that may optionally be added for enhancing the permeation of the solution are preferably not more than 1 wt %, more preferably not more than 0.5 wt %; and is preferably not less than 0.01 wt %, more preferably not less than 0.15 wt %.

The photoresist stripping solution according to the first aspect of the invention can advantageously be used with all photoresists, whether negative- or positive-working, that can be developed with aqueous alkaline solutions. Such photo resists include, but are not limited to, (i) a positive-working photoresist containing a naphthoquinonediazide compound and a novolak resin, (ii) a positive-working photoresist containing a compound that generates an acid upon exposure, a compound that decomposes with an acid to have a higher solubility in aqueous alkali solutions, and an alkali-soluble resin, (iii) a positive-working photoresist containing a compound that generates an acid upon exposure and an alkali-soluble resin having a group that decomposes with an acid to have a higher solubility in aqueous alkali solutions, and (iv) a negative-working photoresist containing a compound that generates an acid upon illumination with light, a crosslinker and an alkali-soluble resin.

According to the second aspect of the invention, photoresists are stripped away by one of two methods which have the following steps in common: forming a photoresist pattern by lithography on a substrate having conductive metallic layers and insulating layers, and selectively etching these layers, with the photoresist pattern used as a mask, to from a fine-line circuit. After these steps, the photoresist pattern is immediately stripped away (method I) or the photoresist pattern after etching step is subjected to plasma ashing and the ashed residues such as modified photoresist films and metal depositions are stripped away (method II).

An example of method I in which the photoresist film is stripped away immediately after etching comprises:

(I) providing a photoresist layer on a substrate;

(II) selectively exposing said photoresist layer;

(III) developing the exposed photoresist layer to provide a photoresist pattern;

(IV) etching the substrate using said photoresist pattern as a mask; and

(IV) stripping the photoresist pattern from the etched substrate using the photoresist stripping solution according to the first aspect of the invention.

An example of method II in which the modified photoresist films as well as metal depositions resulting from plasma ashing are stripped away after etching comprises:

(I) providing a photoresist layer on a substrate;

(II) selectively exposing said photoresist layer;

(III) developing the exposed photoresist layer to provide a photoresist pattern;

(IV) etching the substrate using said photoresist pattern as a mask;

(V) plasma ashing the photoresist pattern; and

(VI) stripping the ashed and modified photoresist pattern from the substrate using the photoresist stripping solution according to the first aspect of the invention.

The stripping solution of the invention is particularly suitable for use on a substrate having a metallic conductor pattern, or a metallic conductor pattern and an overlying inorganic material layer such as polysilicon film formed thereon, and it has an outstanding strippability of photoresist films as well as modified photoresist films, and corrosion protection of the substrate.

As the metallic conductor pattern, an aluminum (Al) conductor pattern, a copper (Cu) conductor pattern and the like may be used. The present invention exhibits excellent effects particularly in the case where the Cu conductor pattern is used.

The term “copper (Cu) conductor pattern” as used in the invention encompasses not only conductor patterns made of pure copper but also conductor patterns made of copper-based alloys containing Cu as a main component (amounting to, e.g., 90 wt % or more) together with other metals such as Al.

Examples of the inorganic material layer include, particularly in the production of a liquid crystal device, a film comprising a semiconductor material, such as a polysilicon film and an amorphous silicon film, but it is not limited to these examples. It has been difficult by the conventional photoresist stripping solution to attain both the strippability of the photoresist and the corrosion prevention of a substrate having a metallic conductor pattern and an inorganic material layer. The present invention have attained both the effects.

In the case where both metallic conductor patterns and overlying inorganic material layers such as amorphous silicon films or polysilicon films are formed on a substrate, it is often used Al and an Al alloy for the metallic conductor patterns. In such a case, the invention exhibits excellent corrosion prevention both to Al-wired pattern and an Al alloy-wired pattern and to the inorganic material layers.

In the above-described method II, after plasma ashing, a photoresist residue (modified photoresist film) and a metallic deposition occurred in etching step, adhere to or remain as residues on the surface of the substrate. The residues can be stripped away from the substrate by bringing into contact with the photoresist stripping solution according to the first aspect of the invention. Plasma ashing is initially intended to remove the photoresist pattern but a portion of it occasionally remains deteriorated after ashing. The stripping solution of the invention is particularly effective in completely stripping the deteriorated film and the residues (depositions) that remain after the etching or ashing step.

The coating, drying, exposing, developing, etching and ashing steps are all conventional and not limited in any particular way. Etching may be performed either wet or dry, though it is preferred in the invention to employ wet etching. Particularly, for a glass substrate used in a liquid-crystal panel device, an acidic etching solution, such as phosphoric acid, nitric acid and acetic acid, is preferably used as an etching solution (etchant).

After the developing step (III) (in methods I and II) or after the stripping step (V) (in method I) or (VI) (in method II), conventional after-treatments may be applied, namely, rising with organic solvents, water, etc. and drying.

Depending on the type of the photoresist used, post-exposure bake may be performed as is commonly the case for chemically amplified photoresists. Post-bake may also be performed after the formation of the photoresist pattern.

The stripping process is typically performed by dip method or a shower method. The time of its duration is not limited to any particular value insofar as it is long enough to achieve the intended stripping. Normally, the stripping process lasts for about 10-20 minutes.

In the case of using a substrate having a copper (Cu) conductor pattern formed thereon as the metal conductor pattern, it is preferable to apply the following methods by a dual damascene processes described below.

That is, a method of stripping photoresists which comprises:

(I) providing an etching stopper layer on a substrate having a Cu conductor pattern formed thereon, and further providing an interlevel dielectric layer thereon;

(II) providing a photoresist layer on the interlevel dielectric layer;

(III) selectively exposing said photoresist layer;

(IV) developing the exposed photoresist layer to form a photoresist pattern;

(V) etching, with the photoresist pattern used as a mask, the interlevel dielectric layer to leave the etching stopper layer;

(VI) stripping the photoresist pattern from the interlevel dielectric layer using the photoresist stripping solution according to the first aspect of the invention; and

(VII) stripping the etching stopper layer remained.

Another method of stripping photoresists which comprises:

(I) providing an etching stopper layer on a substrate having a Cu conductor pattern formed thereon, and further providing an interlevel dielectric layer thereon;

(II) providing a photoresist layer on the interlevel dielectric layer;

(III) selectively exposing said photoresist layer;

(IV) developing the exposed photoresist layer to form a photoresist pattern;

(V) etching, with the photoresist pattern used as a mask, the interlevel dielectric layer to leave the etching stopper layer;

(VI) plasma ashing the photoresist pattern;

(VII) stripping the ashed and modified photoresist pattern from the interlevel dielectric layer using the photoresist stripping solution according to the first aspect of the invention; and

(VIII) stripping the etching stopper layer remained.

After the developing step (IV) (in the former dual damascene process) or after the stripping step (VII) (in the former dual damascene process) or (VIII) (in the latter dual damascene process), conventional after-treatments may be applied, namely, rising with organic solvents, water, etc. and drying.

In the dual damascene processes described above, the etching stopper layer is exemplified by a nitride film such as an SiN film. By etching the interlevel dielectric layer while leaving the etching stopper layer, the Cu conductor is substantially free from the effects of the subsequent plasma ashing.

The Cu conductor formed on the substrate may be a Cu alloy conductor comprising Cu as the main component (amounting to, e.g., 90 wt % or more) together with other metals such as Al. Alternatively, a pure Cu conductor may be used therefor.

Exemplary stripping method by a dual damascene process including an ashing treatment will be described in greater detail.

Firstly, a Cu conductor pattern is formed on a substrate such as a silicon wafer or a glass plate, and an etching stopper layer (for example, an SiN film) is formed thereon, if desired. Then, an interlevel dielectric layer (for example, an organic SOG layer) is further formed thereon.

Next, a photoresist composition is applied onto the interlevel dielectric layer, dried, exposed and developed to form a photoresist pattern. The conditions for exposure and development may be appropriately selected depending on the photoresist and its specific use. In exposure, the photoresist layer may be exposed through a desired mask pattern to a light source emitting actinic radiations (e.g., UV light, far-UV light, excimer laser, X-rays or electron beams) such as a low-pressure mercury-vapor lamp, a high-pressure mercury-vapor lamp, an ultra-high pressure mercury-vapor lamp or a xenon lamp. Alternatively, the photoresist layer is illuminated with controlled electron beams. Thereafter, post-exposure bake is optionally performed if needed.

Then, pattern development is performed with a photoresist developer to form a predetermined photoresist pattern. The method of development is not limited to any particular type and various methods may be employed as appropriate for the specific object. Examples thereof include dip development in which the photoresist-coated substrate is immersed in the developer for a specified time and then washed with water and dried; paddle development in which the developer is dripped on the surface of the applied photoresist coat which is thereafter left to stand for a specified time, washed with water and dried; and spray development in which the photoresist surface is sprayed with the developer and thereafter washed with water and dried.

Subsequently, with the photoresist pattern used as a mask, the interlevel dielectric layer is selectively etched in such a manner as to leave the etching stopper layer, and plasma ashed to thereby remove the unwanted photoresist layer. Then the etching stopper layer remained is removed to form a fine-line circuit (hole pattern). In the case of performing plasma ashing, post-ashing photoresist residue (modified films) and post-etching residue (metal deposition) adhering to the substrate surface can be stripped away by bringing these residues on the substrate into contact with the stripping solution according to the invention.

Etching may be performed on either a wet or dry basis or two methods may be applied in combination, though it is preferred in the invention to employ dry etching.

Stripping is usually performed by dipping or spraying. It is sufficient to carry out stripping for 10-20 minutes in usual, though the invention is not limited thereto.

After the step of stripping as described above, the substrate is rinsed with organic solvents or water.

After forming the pattern (particularly the hole pattern) by the above-described method, Cu is buried in it by a suitable means such as plating to provide electrical continuity. If desired, the same procedure may be repeated to form an upper level comprising an interlevel dielectric layer, a hole pattern and electrical continuity so as to fabricate a multi-level Cu-wired board.

The stripping solution according to the invention and the stripping method using the same have excellent effects in stripping away post-ashing photoresist films (modified films) and post-etching residue (metal deposition) even in highly integrated, high-density substrates, and, in protecting various metal conductors, metallic layers, etc. from corrosion in the step of rinsing.

To further illustrate the invention in greater detail, and not by way of limitation, the following examples will be given. Unless otherwise noted, all amounts of the components are expressed in wt %.

### EXAMPLE 1

[Strippability of Photoresist Film, Corrosion of Cu Conductor Pattern]

An etching stopper layer comprising an SiN film was provided on a Cu-wired substrate and then an interlevel dielectric layer comprising an organic SOG film was further formed thereon. The substrate having layers thusly formed thereon was spin coated with TDUR-PO15PM (product of Tokyo Ohka Kogyo Co., Ltd.) which was a positive-working photoresist and the applied coat was pre-baked at 80° C. for 90 seconds to form a photoresist layer of 0.7 μm in film thickness.

This photoresist layer was exposed to light from FPA3000EX3 (product of Nikon Corp.) through a mask pattern and then developed with an aqueous solution of 2.38 wt % TMAH (tetramethylammonium hydroxide) to form a photoresist pattern (hole space 0.25 μm). Next, it was post-baked at 110° C. for 90 seconds.

Subsequently, the substrate having the photoresist pattern thus formed was dry-etched. The etching was stopped as to leave the SiN layer completely, and the thusly treated substrate was dipped in each stripping solution having the composition as listed in Table 1 at 80° C. for 10 minutes to thereby strip the photoresist films.

The substrate is further dipped in an isopropyl alcohol solution at 23° C. for 5 minutes and then dipped in pure water at 23° C. for 5 minutes, so as to conduct a rinsing treatment.

The corrosion of Cu conductor pattern on the substrate and the strippability of the photoresist film were evaluated by examining photographs taken with a SEM (scanning electron microscope). The results are shown in Table 2.

The criteria for evaluation were as follows.

(Corrosion of Cu Conductor Pattern)

A: no visible corrosion of Cu conductor pattern;

B: slightly visible corrosion of Cu conductor pattern;

C: extensively visible corrosion of Cu conductor pattern.

(Strippability of Photoresist Film)

A: the photoresist film was completely stripped away;

B: the photoresist film remained slightly;

C: the photoresist film remained considerably.

[Strippability of Photoresist Residue after Ashing, Corrosion of Cu Conductor Pattern]

To evaluate the strippability of the photoresist residue (modified photoresist film) after ashing and the corrosion of Cu conductor pattern, the following test was performed.

Development with an aqueous solution of 2.38 wt % TMAH (tetramethylammonium hydroxide) and post-bake were performed in the manner described above. Then, dry etching was performed until a slight thickness of the etching stopper (SiN layer) was left intact. Subsequently, the photoresist layer was removed by ashing with an ashing apparatus model TCA-38228 (product of Tokyo Ohka Kogyo Co., Ltd.). Following another dry etching, the residual SiN layer was removed. Any residue on the substrate was stripped with a stripping solution having the same recipe as shown in Table 1.

The strippability of the residue and the corrosion of Cu conductor pattern were evaluated and the results were the same as those obtained in the above-described evaluation of the strippability of the photoresist film and the corrosion of Cu conductor pattern.

### EXAMPLES 2-5

A photoresist film was stripped by the same method as in Example 1, except that the photoresist stripping solution was replaced by those having the recipes shown in Table 1. The strippability of the photoresist film and the corrosion of Cu conductor pattern were evaluated to give the results also shown in Table 1. The results are shown in Table 2.

Ashing was also performed by the same method as in Example 1, and the strippability of the residue and the corrosion of Cu conductor pattern were evaluated. In each of Examples 2-5, the results were the same as those obtained in the evaluation of the strippability of the photoresist film and the corrosion of Cu conductor pattern.

### COMPARATIVE EXAMPLES 1-8

A photoresist film was stripped by the same method as in Example 1, except that the photoresist stripping solution was replaced by those having the recipes shown in Table 1. The strippability of the photoresist film and the corrosion of Cu conductor pattern were evaluated to give the results also shown in Table 1. The results are shown in table 2.

Ashing was also performed by the same method as in Example 1, and the strippability of the residue and the corrosion of Cu conductor pattern were evaluated. In each of Comparative Examples 1-8, the results were the same as those obtained in the evaluation of the strippability of the photoresist film and the corrosion of Cu conductor pattern. [Corrosion of polysilicon film]

### EXAMPLES 1-5, COMPARATIVE EXAMPLES 1-8

An SiO₂ substrate having an Al alloy conductor pattern and an overlying polysilicon film formed thereon was spin-coated with a positive-working photoresist comprising naphthoquinone diazide compound and novolak resin (“THMR-iP3300” of Tokyo Ohka Kogyo Co., Ltd.). Then, it was prebaked at 90° C. for 90 seconds, so that there was obtained a 2.0-μm thick photoresist layer. After that, the photoresist layer was exposed through a mask pattern using NSR-2005i10D (a product of Nikon Corporation). The exposed photoresist was developed with an aqueous solution of 2.38 wt % tetramethylammonium hydroxide (TMAH). The resulting photoresist pattern underwent post-baking at 120° C. for 90 seconds.

Subsequently, the substrate underwent etching with a mixed acidic etching solution of phosphoric acid, nitric acid and acetic acid as an etchant. After that the substrate was washed with water.

The photoresist stripping solutions (maintained at 60° C.) having the compositions shown in Table 1 each was sprayed on the thusly treated substrate by a shower method to conduct a stripping treatment of the photoresist film. The substrate after the stripping treatment was sufficiently subjected to a rinsing treatment with pure water, and the corrosion of the polysilicon film was evaluated by examining photographs taken with a SEM (scanning electron microscope). The results are shown in Table 2.

The criteria for evaluation were as follows.

(Corrosion of Polysilicon Film)

A: no visible corrosion of polysilicon film;

B: slightly visible corrosion of polysilicon film;

C: extensively visible corrosion of polysilicon film.

TABLE 1

| | Photoresist stripping solution (wt %) | | | | |
|---|---|---|---|---|---|
| | Component (a) | Component (b) | Component (c) | Component (d) | Other component |
| Example 1 | MEA (48) | NMP (30) | water (20) | IR-42 (2) | — |
| Example 2 | MEA (39) | NMP (40) | water (20) | IR-42 (1) | — |
| Example 3 | MEA (58) | NMP (20) | water (20) | IR-42 (2) | — |
| Example 4 | DGA (30) | DMSO (40) | water (29) | BT-GL (1) | — |
| Example 5 | DGA (60) | NMP (20) | water (16) | IR-42 (4) | — |
| Comparative | MEA (35) | DMSO (15) | water (45) | — | A-A (5) |
| Example 1 | | | | | |
| Comparative | MEA (69) | NMP (10) | water (10) | BT (1) | PC (10) |
| Example 2 | | | | | |
| Comparative | DGA (69) | NMP (20) | — | BT (1) | DHA (10) |
| Example 3 | | | | | |
| Comparative | MEA (10) | DMSO (55) | water (15) | — | PC (5) |
| Example 4 | | | | | HA (15) |
| Comparative | DGA (49.95) | NMP (49.95) | — | BT-GL (0.1) | — |
| Example 5 | | | | | |
| Comparative | | | | | |
| Example 6 | MEA (17.5) | NMP (17.4) | water (45) | BT-GL (0.1) | xylitol (20) |
| Comparative | DEGA (48.5) | HEP (48.5) | — | — | vicine (3) |
| Example 7 | | | | | |
| Comparative | | | | | |
| Example 8 | MEA (47.5) | NMP (47.5) | — | IR-42 (5) | — |

The abbreviations in Table 1 for the respective components have the following meanings: MEA, monoethanolamine; DGA, 2-(2-aminoethoxy)ethanol; DEGA, diethylene glycol amine; NMP, N-methyl-2-pyrrolidone; DMSO, dimethylsulfoxide; HEP, N-hydroxyethyl-2-pyrrolidone; IR-42, 2,2′-{[(methyl-1H-benzotriazole-1-yl)methyl]imino}bisethanol; BT-GL, 1,2-dihydroxypropylbenzotriazole; BT, benzotriazole; A-A, “Surfynol 440” (product of Air Product and Chemicals Inc.); PC, pyrocatechol; DHA, diethylhydroxylamine; and HA, hydroxylamine.

TABLE 2

| | Corrosion of | Corrosion of | Strippability |
|---|---|---|---|
| | polysilicon | Cu conductor | of photoresist |
| | film | pattern | film |
| Example 1 | A | A | A |
| Example 2 | A | A | A |
| Example 3 | A | A | A |
| Example 4 | A | A | A |
| Example 5 | A | A | A |
| Comparative | C | C | A |
| Example 1 | | | |
| Comparative | A | A | B |
| Example 2 | | | |
| Comparative | A | A | C |
| Example 3 | | | |
| Comparative | C | C | A |
| Example 4 | | | |
| Comparative | A | B | C |
| Example 5 | | | |
| Comparative | A | C | A |
| Example 6 | | | |
| Comparative | C | C | C |
| Example 7 | | | |
| Comparative | A | A | C |
| Example 8 | | | |

It is apparent from the results in Table 2 that it has been confirmed that Examples 1-5 are excellent in corrosion prevention of a metallic conductor pattern and an inorganic material layer and also excellent in strippability of a photoresist film. On the other hand, in Comparative Examples 1-8, those effects cannot be obtained of corrosion prevention against a metallic conductor pattern and an inorganic material layer, and the strippability of a photoresist film.

As described in detail in the foregoing, a photoresist stripping solution and a method of stripping photoresists using the same are provided by the invention, that is excellent not only in stripping photoresists but also in protecting substrates from corrosion, having metallic conductor patterns, especially copper (Cu) conductor patterns, formed thereon, or having metallic conductor patterns and overlying inorganic material layers formed thereon. The invention is suitable for use in the fabrication of semiconductor devices, such as ICs and LSIs, as well as liquid-crystal panel devices.

What is claimed is:

1. A photoresist stripping solution comprising (a) a nitrogen-containing organic hydroxyl compound, (b) a water soluble organic solvent, (c) water, and (d) a benzotriazole compound represented by the following general formula (I): 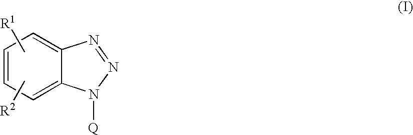
wherein Q is a hydrogen atom, a hydroxyl group or a substituted or unsubstituted hydrocarbon group having 1-10 carbon atoms (provided that said hydrocarbon group may have an amide bond or an ester bond in the structure), an aryl group or the following formula: 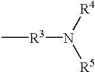
(wherein R³ represents an alkyl group having 1-6 carbon atoms; and R⁴ and R⁵ are each independently a hydrogen atom, a hydroxyl group or a hydroxyalkyl group or an alkoxyalkyl group having 1-6 carbon atoms); and R¹ and R² are each independently a hydrogen atom, a substituted or unsubstituted hydrocarbon group having 1-10 carbon atoms, a carboxyl group, an amino group, a hydroxyl group, a cyano group, a formyl group, a sulfonylalkyl group or a sulfo group.

2. The photoresist stripping solution according to claim 1, wherein component (a) is an amine having acid dissociation exponents (pKa) in an aqueous solution at 25° C. of 7.5-13.

3. The photoresist stripping solution according to claim 1, wherein component (b) is at least one selected from the group consisting of N-methyl-2-pyrrolidone and dimethylsulfoxide.

4. The photoresist stripping solution according to claim 1, wherein Q in the general formula (I) represents a group represented by the following formula: 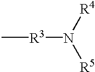
(wherein R³, R⁴ and R⁵ are each as defined in claim 1), a hydrogen atom, an alkyl group having 1-3 carbon atoms, a hydroxyalkyl group having 1-3 carbon atoms or a hydroxyl group.

5. The photoresist stripping solution according to claim 1, wherein the photoresist stripping solution comprises 10-65 wt % of component (a), 10-60 wt % of component (b), 5-50 wt % of component (c), and 0.1-10 wt % of component (d).

6. The photoresist stripping solution according to claim 1, wherein the stripping solution further include at least one compound selected from the group consisting of N-alkyl-2-pyrrolidone represented by the following general formula (II): 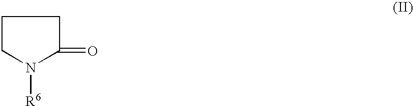
(wherein R⁶ represents an alkyl group having 6-20 carbon atoms) and an acetylene alcohol/alkylene oxide adduct.

7. The photoresist stripping solution according to claim 6, wherein the acetylene alcohol/alkylene oxide adduct is a compound represented by the following general formula (IV): 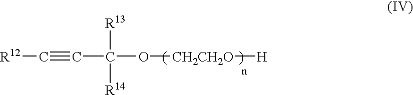
where R¹² is a hydrogen atom or 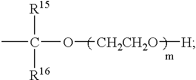
R¹³, R¹⁴, R¹⁵, and R¹⁶ are each independently a hydrogen atom or an alkyl group having 1-6 carbon atoms.

8. The photoresist stripping solution according to claim 1, wherein the stripping solution is used for stripping a photoresist provided on a substrate having a metallic conductor pattern or a metallic conductor pattern and an overlying inorganic material layer formed thereon.

9. The photoresist stripping solution according to claim 8, wherein the metallic conductor pattern is a Cu conductor pattern.

10. A method of stripping photoresists comprising: etching a substrate, which have a metallic conductor pattern formed thereon, or have a metallic conductor pattern and an overlying inorganic material layer formed thereon, using a photoresist pattern formed on the substrate as a mask; and stripping the photoresist pattern using the photoresist stripping solution according to any one of claims 1 to 8.

11. The method of stripping photoresists according to claim 10, wherein the metallic conductor pattern is a Cu conductor pattern.

12. A method of stripping photoresists comprising: etching a substrate, which have a metallic conductor pattern formed thereon, or have a metallic conductor pattern and an overlying inorganic material layer formed thereon, using a photoresist pattern formed on the substrate as a mask; ashing the substrate; and stripping residues occurred after ashing using the photoresist stripping solution according to any one of claims 1 to 8.

13. The method of stripping photoresists according to claim 12, wherein the metallic conductor pattern is a Cu conductor pattern.
